(19) United States
(12) Patent Application Publication
(10) Pub. No.: US 2026/0190886 A1
(43) Pub. Date: Jul. 2, 2026

(54) METHOD FOR MANUFACTURING SEMICONDUCTOR DEVICE AND SEMICONDUCTOR DEVICE

(71) Applicant: HANGZHOU FULLSEMI SEMICONDUCTOR CO., LTD., Hangzhou (CN)

(72) Inventor: Wuyang NIE, Hangzhou (CN)

(73) Assignee: HANGZHOU FULLSEMI SEMICONDUCTOR CO., LTD., Hangzhou (CN)

(21) Appl. No.: 19/314,023

(22) Filed: Aug. 29, 2025

(30) Foreign Application Priority Data
Dec. 26, 2024 (CN) 2024119474111

(51) Int. Cl. H01L 21/311; H01L 21/02

(52) U.S. Cl. CPC H10P 50/283; H10P 70/23

(57) ABSTRACT

The present disclosure discloses a method for manufacturing a semiconductor device and a semiconductor device. The method includes: providing a wafer, wherein a metal layer containing aluminum and a passivation layer are formed on the wafer, the passivation layer is a multi-layer structure sequentially stacked on the metal layer, and the passivation layer includes an oxide dielectric layer; etching the passivation layer using a plurality sets of etching gases corresponding to the multi-layer structure to form an opening region exposing a portion of the metal layer; performing a cleaning process to at least clean by-products in the opening region; wherein the plurality sets of etching gases include a first etching gas for etching the oxide dielectric layer, the first etching gas includes a first fluorine-containing gas with a low carbon-fluorine ratio and a first auxiliary gas configured to remove a carbon-containing polymer generated during an etching process.

### FIELD OF TECHNOLOGY

The present disclosure relates to the field of semiconductor technology, and in particular to a method for manufacturing a semiconductor device and a semiconductor device.

### BACKGROUND

In semiconductor manufacturing processes, pads need to be formed to prepare for subsequent packaging processes. In conventional techniques, pads are typically formed by performing dry etching on a covering layer of a metal layer (e.g., aluminum) followed by cleaning. However, during subsequent defect inspection, densely distributed polymer defects are still observed in an exposed region of the pads on the wafer. These polymers exhibit strong adhesion to the pad regions and are difficult to remove through conventional cleaning processes, which compromises pad performance and reliability, and ultimately affects the yield of semiconductor device products.

### SUMMARY

In view of at least one technical problem in the related art, the purpose of the present application is to provide a preparation method of a semiconductor device.

In one aspect, the present disclosure provides a method for manufacturing a semiconductor device, comprising:
providing a wafer, wherein a metal layer containing aluminum and a passivation layer are formed on the wafer, the passivation layer is a multi-layer structure sequentially stacked on the metal layer, and the passivation layer comprises an oxide dielectric layer;
etching the passivation layer using a plurality sets of etching gases corresponding to the multi-layer structure to form an opening region exposing a portion of the metal layer;
performing a cleaning process to at least clean by-products in the opening region; wherein
the plurality sets of etching gases comprise a first etching gas for etching the oxide dielectric layer, the first etching gas comprises a first fluorine-containing gas with a low carbon-fluorine ratio and a first auxiliary gas, and the first auxiliary gas is configured to remove a carbon-containing polymer generated during an etching process.

In some embodiments, the first fluorine-containing gas comprises trifluoromethane and carbon tetrafluoride; in the first etching gas, a gas flow ratio of the trifluoromethane to the carbon tetrafluoride is 5:(24-26); and/or
a gas flow ratio of the first fluorine-containing gas to the first auxiliary gas is less than 4.

In some embodiments, the first auxiliary gas comprises oxygen;
in the first etching gas, a gas flow ratio of the trifluoromethane to the oxygen is 10:(19-21).

In some embodiments, a gas flow range of carbon tetrafluoride contained in the first fluorine-containing gas is in a range of 480 sccm-520 sccm, and a gas flow range of the first auxiliary gas is in a range of 190 sccm-210 sccm

In some embodiments, a photoresist layer is formed on the passivation layer, and the first etching gas further comprises a second auxiliary gas for hardening the photoresist layer; and etching the passivation layer using a plurality sets of etching gases corresponding to the multi-layer structure comprises:
etching corresponding layer structures in the passivation layer in stages using the photoresist layer as a mask and the plurality sets of etching gases; after etching the passivation layer, a remaining thickness of the photoresist layer being greater than a preset thickness value.

In some embodiments, the second auxiliary gas comprises hydrogen, and a gas flow ratio of the second auxiliary gas to the first auxiliary gas is (1-2):(19-21).

In some embodiments, the preset thickness value is greater than or equal to 1000 angstroms.

In some embodiments, the passivation layer further comprises an etching stop layer, and the etching stop layer is located between the metal layer and the oxide dielectric layer; the method further comprises:
after etching the passivation layer to the etching stop layer, etching the opening region using a second etching gas to remove the by-products generated during the etching process.

In some embodiments, the second etching gas comprises a second fluorine-containing gas with a low carbon-fluorine ratio and a third auxiliary gas, and a gas flow ratio of the second fluorine-containing gas to the third auxiliary gas is 1:(18-20).

In some embodiments, the second etching gas satisfies at least one of:
the second fluorine-containing gas comprising the carbon tetrafluoride;
the third auxiliary gas comprising the oxygen;
a gas flow range of the third auxiliary gas is in a range of 1800 sccm-2000 sccm.

In another aspect, the present disclosure further provides a semiconductor device, wherein the semiconductor device is manufactured by any method for manufacturing the semiconductor device described above.

In another aspect, the present disclosure further provides a chip, comprising any semiconductor device described above.

In another aspect, the present disclosure further provides an electronic apparatus, comprising any semiconductor device described above.

The method for manufacturing the semiconductor device and the semiconductor device of the present disclosure have at least the following beneficial effects:

By etching the multilayer structure in the passivation layer on the wafer using the plurality sets of etching gases, the opening region of the metal layer containing aluminum is formed and cleaned. The plurality sets of etching gases comprise the first etching gas for etching the oxide dielectric layer in the passivation layer, and the first etching gas comprises the first fluorine-containing gas with a low carbon-fluorine ratio and the first auxiliary gas. By adjusting the etching gas to the first fluorine-containing gas with a low carbon-fluorine ratio to remove the fluorine-containing gas with a high carbon-fluorine ratio, the aluminum-containing polymer defects formed during the etching process of the passivation layer can be fundamentally reduced. In addition, by adding the first auxiliary gas to the first etching gas to remove the carbon-containing polymer generated during the etching process, and etching in combination with the first fluorine-containing gas with a low carbon-fluorine ratio, the polymer defects formed during the etching process of the passivation layer can be fundamentally solved, which not only reduces the subsequent cleaning burden, but also improves the performance and reliability of the formed pads without increasing the process cost, thereby improving the yield of semiconductor device products.

### BRIEF DESCRIPTION OF THE DRAWINGS

In order to more clearly illustrate the technical solutions and advantages in the embodiments of the present disclosure or the related art, the drawings required for use in the embodiments or the related art descriptions are briefly introduced below. Obviously, the drawings described below are only some embodiments of the present disclosure. For those having ordinary skills in the art, other drawings can be obtained based on these drawings without creative work.

FIG. 1 is a schematic diagram of a defect detection result of a wafer corresponding to a pad formed by an etching gas used in the related art.

FIG. 2 is a flowchart of a method for manufacturing a semiconductor device according to some embodiments of the present disclosure.

FIG. 3 is a schematic structural diagram of a passivation layer before and after etching according to some embodiments of the present disclosure;

FIG. 4 is a schematic diagram of a process of a change in an etching process parameter according to some embodiments of the present disclosure;

FIG. 5 is a schematic diagram of a defect detection result of a wafer corresponding to a pad formed in Example 1 of the present disclosure.

FIG. 6 is a schematic diagram of a defect detection result of a wafer corresponding to a pad formed in Comparative Example 1 of the present disclosure.

FIG. 7 is a schematic diagram of a defect detection result of a wafer corresponding to a pad formed in Comparative Example 2 of the present disclosure.

### REFERENCE SIGNS IN THE FIGURES

301, photoresist layer, 302, nitride dielectric layer, 303, silicon-rich oxide layer, 304, silicon oxide layer, 305, oxynitride dielectric layer, 306, etching stop layer, 307, metal layer; 301′, photoresist layer after etching.

### DETAILED DESCRIPTION

The following will be combined with the drawings in the embodiments of the present disclosure to clearly and completely describe the technical solutions in the embodiments of the present disclosure. Obviously, the described embodiments are only part of the embodiments of the present disclosure, not all of the embodiments. Based on the embodiments in the present disclosure, all other embodiments obtained by those having ordinary skills in the art without creative work are within the scope of protection of the present disclosure.

The “one embodiment” or “embodiment” referred to below refers to a specific feature, structure or characteristic that may be comprised in at least one implementation of the present invention. In the description of the present invention, unless otherwise clearly specified and limited, the orientation or position relationship indicated by the terms “upper”, “lower”, “left”, “right”, “top”, “bottom”, etc. is based on the orientation or position relationship shown in the drawings, which is only for the convenience of describing the present invention and simplifying the description, rather than indicating or implying that the device or element referred to must have a specific orientation, be constructed and operated in a specific orientation, and therefore cannot be understood as a limitation of the present invention. In addition, the terms “first” and “second” are only used for descriptive purposes, and cannot be understood as indicating or implying relative importance or implicitly indicating the number of technical features indicated. Thus, the features defined as “first” and “second” may explicitly or implicitly comprise one or more of the features. Moreover, the terms “first”, “second”, etc. are used to distinguish similar objects, and are not necessarily used to describe a specific order or sequence. It should be understood that the data used in this way can be interchangeable where appropriate, so that the embodiments of the present invention described herein can be implemented in an order other than those illustrated or described herein.

When a numerical range is disclosed in this application, the above range is deemed to be continuous and comprises the minimum and maximum values of the range, as well as each value between such minimum and maximum values. Furthermore, when a range refers to an integer, each integer between the minimum and maximum values of the range is comprised. In addition, when multiple ranges are provided to describe features or characteristics, the range can be merged. In other words, unless otherwise indicated, all ranges disclosed herein should be understood to comprise any and all sub-ranges comprised therein. For example, a specified range of “1 to 10” or “1˜10” should be deemed to comprise any and all sub-ranges between the minimum value 1 and the maximum value 10. Specifically, exemplary sub-ranges of the range 1 to 10 comprise, but are not limited to, 1 to 6.1, 3.5 to 7.8, 5.5 to 10, etc.

It should be understood that when describing the structure of a component, when a layer or a region is referred to as being located “on” or “above” another layer or another region, it may mean that it is directly located on another layer or another region, or that other layers or regions are comprised between it and another layer or another region. Moreover, if the component is turned over, the layer or the region will be located “below” or “beneath” another layer or another region.

In the related art, the cover layer (e.g., aluminum) on the metal layer is usually dry-etched and cleaned to form a pad. However, in the subsequent defect detection process, the wafer still has densely distributed polymer defects in the opening region of the pad. These polymers have a relatively high adhesion to the pad region and are difficult to remove through traditional cleaning processes, which reduces the performance and reliability of the pad, and further affects the yield of semiconductor device products.

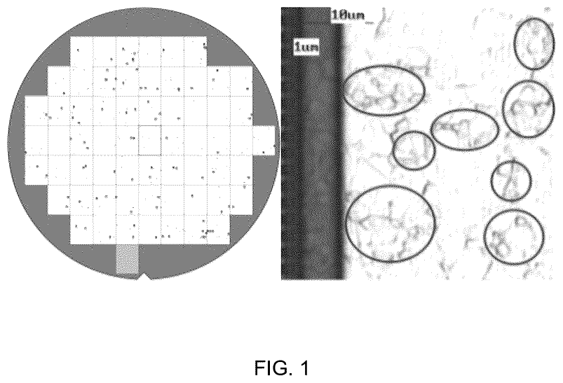

Specifically, in the related art, for example, the cover layer on the aluminum-copper alloy is dry-etched, and the etching gas used in the original old process is C₄F₈ (octafluorocyclobutane), CHF₃ (trifluoromethane), CF₄ (carbon tetrafluoride) and O₂ (oxygen). Exemplarily, in the stage of etching the oxide layer in the cover layer, the gas flow rate of C₄F₈, CHF₃, CF₄ and O₂ may be 28 sccm, 100 sccm, 420 sccm and 120 sccm, respectively. Then photoresist removal and cleaning are performed to form the pad, and finally the wafer corresponding to the formed pad is subjected to defect detection, and the wafer detection result is shown in FIG. 1. FIG. 1 is a schematic diagram of a defect detection result of a wafer corresponding to a pad formed by an etching gas used in the related art, wherein the left figure in FIG. 1 is a schematic diagram of electronic scanning of the wafer, and the right figure in FIG. 1 is an optical micrograph of a chip unit in the wafer in the left figure. As can be seen from FIG. 1, there are densely distributed polymer defects (e.g., a circled portion in the right figure) in the opening region of the pad of the wafer. The inventors found that these polymers are formed by the fluorine in the etching gas and the aluminum in the etching region, and these aluminum-containing polymers have a relatively high adhesion with the aluminum in the pad region, resulting in the subsequent cleaning ability of the traditional cleaning process being insufficient to remove these polymer regions, affecting the yield of semiconductor device products.

In order to solve the above polymer defect problem, the related art mainly considers increasing the ability of polymer removal. For example, by adding gas to remove the polymer in the photoresist removal stage, the ability of polymer removal in the photoresist removal stage is increased. However, the added gas is easy to corrode the electrostatic chuck (ESC), greatly shortening the service life of the ESC and increasing production costs. In addition, since the ability of polymer removal is jointly determined by the photoresist removal stage and the cleaning stage, the fluctuation of any machine parameter affects the final removal effect of the polymer, resulting in low product stability.

In view of this, the present disclosure provides a method for manufacturing a semiconductor device and a semiconductor device to solve the technical problems caused by the polymer defects generated during dry etching in the related art.

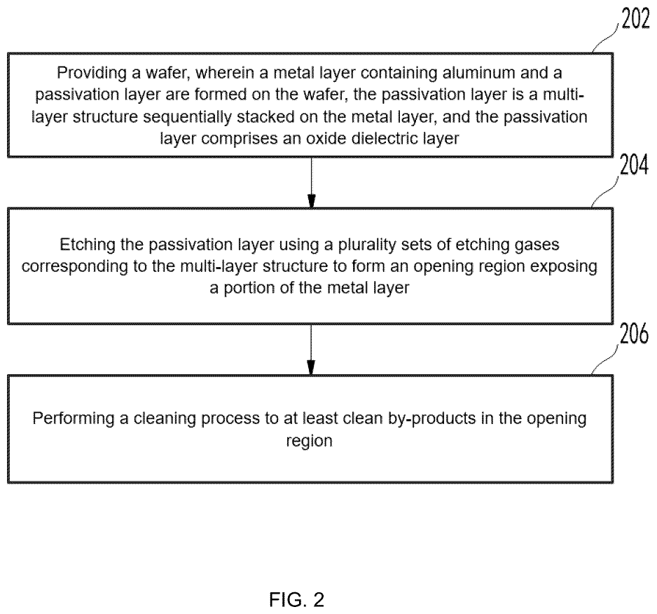

FIG. 2 is a flowchart of a method for manufacturing a semiconductor device according to some embodiments of the present disclosure. It should be understood that the operation order of some of the following operations can be interchanged. Referring to FIG. 2, the method for manufacturing the semiconductor device comprises the following steps:

In operation 202, providing a wafer, wherein a metal layer containing aluminum and a passivation layer are formed on the wafer, the passivation layer is a multi-layer structure sequentially stacked on the metal layer, and the passivation layer comprises an oxide dielectric layer.

In this embodiment, the wafer may be a single-layer structure or a multi-layer structure. A material of the wafer comprises one or a combination of a semiconductor material, an insulating material, and a conductor material. The structure and/or material of the wafer is not specifically limited here.

The metal layer containing aluminum and the passivation layer may be sequentially formed on the wafer by a deposition process. Specifically, the metal layer may be located on a surface of the wafer to achieve metal interconnection between chips by forming pads. The passivation layer wraps a surface of the metal layer away from the wafer to play an isolation role. The passivation layer here is the multi-layer structure stacked in sequence.

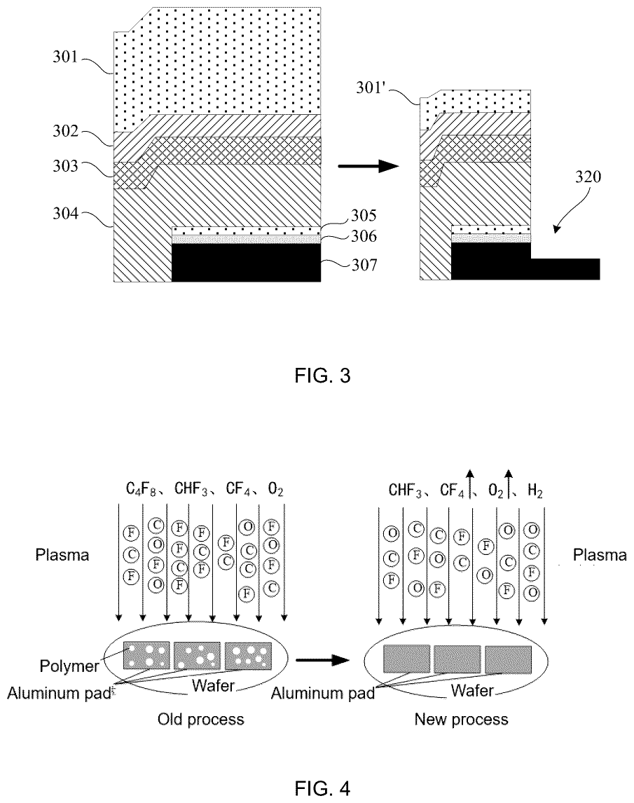

In this embodiment, the passivation layer at least comprises the oxide dielectric layer. Merely by way of example, a material of the oxide dielectric layer may comprise but is not limited to one or more of silicon oxide, silicon-rich oxide (SRO), etc. As shown in FIG. 3, the oxide dielectric layer comprises a silicon-rich oxide layer 303 and a silicon oxide layer 304.

Optionally, the passivation layer further comprises at least one or more of a nitride dielectric layer, an oxynitride dielectric layer, etc. Exemplarily, as shown in FIG. 3, a nitride dielectric layer 302 may be located on a surface of the oxide dielectric layer away from the metal layer 307, and an oxynitride dielectric layer 305 may be located on a surface of the oxide dielectric layer close to the metal layer 307. Merely by way of example, a material of the nitride dielectric layer may comprise but is not limited to silicon nitride, etc., and a material of the oxynitride dielectric layer may comprise but is not limited to silicon oxynitride, etc.

In operation 204, etching the passivation layer using a plurality sets of etching gases corresponding to the multi-layer structure to form an opening region exposing a portion of the metal layer.

The plurality sets of etching gases comprise a first etching gas for etching the oxide dielectric layer. The first etching gas comprises a first fluorine-containing gas with a low carbon-fluorine ratio and a first auxiliary gas, and the first auxiliary gas is configured to remove a carbon-containing polymers generated during the etching process.

In some embodiments, during the dry etching of the passivation layer, the plurality sets of etching gases are used to perform etching to etch the material of a portion of the passivation layer on the metal layer and a portion of the metal layer, forming an opening region 320 that exposes a portion of the metal layer 307 as shown in FIG. 3. The opening region is used as an opening of the pad to realize the metal interconnection between chips. Optionally, the plurality sets of etching gases refer to etching gases comprising a plurality of different gas compositions and/or different gas flow rates. Different sets of etching gases may correspond to etching different layers of the multi-layer structure. For example, for the passivation layer structure shown in FIG. 3, different sets of etching gases may be used to etch the nitride dielectric layer, the oxide dielectric layer and the oxynitride dielectric layer. Each set of etching gases comprises at least a main etching gas, which refers to a suitable gas that can react with the materials of different layers etched in the passivation layer and generate volatile gas products, such as a fluorine-containing etching gas.

In some embodiments, the plurality sets of etching gases comprise the first etching gas for etching the oxide dielectric layer, wherein the first etching gas comprises the first fluorine-containing gas having a low carbon-fluorine ratio and the first auxiliary gas. The low carbon-fluorine ratio refers to low content of carbon and fluorine. Specifically, the fluorine-containing etching gas generally comprises gases with low carbon-fluorine ratios such as CF₄, CHF₃, CH₂F₂, and CH₃F, and gases with high carbon-fluorine ratios such as C₄F₈, C₄F₆, and C₅F₈. Optionally, the first fluorine-containing gas in the first etching gas is selected from at least one gas with a low carbon-fluorine ratio such as CF₄ and CHF₃, rather than a gas with a high carbon-fluorine ratio such as C₄F₈.

In an embodiment, the first auxiliary gas is used to remove the carbon-containing polymer generated during the etching process. Exemplarily, the first auxiliary gas is a gas capable of reducing the generation of the carbon-containing polymer, such as oxygen.

In operation 206, performing a cleaning process to at least clean by-products in the opening region.

In some embodiments, after the etching process is performed, the cleaning process such as a wet process may be performed to clean the formed opening region and the wafer to clean the by-products on the surface of the opening region and on the wafer, such as a residual reactant, etc. Exemplarily, a cleaning agent used in the wet process may comprise but is not limited to hydrofluoric acid, sulfuric acid, etc.

The inventors have conducted elemental analysis on the polymer defects in related technologies and determined that the polymer is aluminum trifluoride (AlF₃) generated by a fluorine element in the etching gas and an aluminum element in the etching region. In order to reduce the polymer defects, the inventors start from reducing the source of polymer generation and first consider reducing the proportion of fluorine in the etching gas. In the related technologies, continuing to use the aforementioned four etching gases C₄F₈, CHF₃, CF₄ and O₂ as an example, among the etching gases used in the original process, C₄F₈ contains the most F atoms. Therefore, the problem of polymer defects is solved by removing the gas C₄F₈ with a high carbon-fluorine ratio and using the first fluorine-containing gas with a low carbon-fluorine ratio.

In the above embodiment, by adjusting the etching gas to the first fluorine-containing gas with a low carbon-fluorine ratio and removing the fluorine-containing gas with a high carbon-fluorine ratio, the aluminum-containing polymer defects formed during the etching process of the passivation layer can be fundamentally reduced. In addition, by adding the first auxiliary gas to the first etching gas to remove the carbon-containing polymer generated during the etching process, and etching in combination with the first fluorine-containing gas with a low carbon-fluorine ratio, the polymer defects formed during the etching process of the passivation layer are fundamentally solved, which not only reduces the subsequent cleaning burden, but also improves the performance and reliability of the formed pad without increasing the process cost, thereby improving the yield of semiconductor device products.

In some embodiments, a ratio of the gas flow rate of the first fluorine-containing gas to the first auxiliary gas is less than 4. Optionally, a gas flow ratio of the first fluorine-containing gas to the first auxiliary gas is in a range of 2-4. Further optionally, the gas flow ratio of the first fluorine-containing gas to the first auxiliary gas is in a range of 2.5-3.5.

In the original old process, the fluorine-containing gas in the etching gas comprises C₄F₈, the gas with a high carbon-fluorine ratio, as well as CHF₃ and CF₄, and oxygen is used as an auxiliary gas. A ratio of a total flow of the fluorine-containing gas (i.e., C₄F₈, CHF₃ and CF₄) to the gas flow of the auxiliary gas (i.e., oxygen) is usually greater than 4. In this embodiment, in addition to not using the gas with a high carbon-fluorine ratio in the first etching gas used to etch the oxide dielectric layer, and completely using the gas with a low carbon-fluorine ratio as the first fluorine-containing gas, the gas flow ratio of the first fluorine-containing gas to the first auxiliary gas is reduced to a value less than 4. That is, the proportion of the first auxiliary gas in the first etching gas is increased to reduce the residual carbon-containing polymer after etching. According to the defect detection result of the wafer, this embodiment can solve the problem of polymer defects in the related art by adjusting the gas process parameter of the etching gas as a whole. In this way, the subsequent cleaning burden is further reduced, which is conducive to improving the yield of semiconductor device products.

In some embodiments, the first fluorine-containing gas comprises trifluoromethane and carbon tetrafluoride. In the first etching gas, a gas flow ratio of trifluoromethane to carbon tetrafluoride is 5:(24-26). Exemplarily, the gas flow ratio may be a boundary value in 5:(24-26) or any integer or decimal value in the range. Further preferably, in the first etching gas, the gas flow ratio of trifluoromethane to carbon tetrafluoride is 5:25.

Continuing to take the aforementioned original process using four etching gases C₄F₈, CHF₃, CF₄ and O₂ for etching as an example, the gas flow rates of CHF₃ and CF₄ in the corresponding etching stages are 100 sccm and 420 sccm, respectively, and the gas flow rate ratio of CHF₃ to CF₄ is 5:21. In this embodiment, the gas flow ratio of trifluoromethane to carbon tetrafluoride is 5:(24-26). By comparison, it can be seen that the gas flow rate of carbon tetrafluoride in the first etching gas is increased in this embodiment. The wafer test results show that by increasing the gas flow rate of carbon tetrafluoride in the first etching gas on the basis of removing the fluorine-containing gas with a high carbon-fluorine ratio, not only can the aluminum fluoride polymer defects be improved, but also the etching rate can be increased to meet the etching rate requirements during the etching process.

In some embodiments, the gas flow rate of carbon tetrafluoride contained in the first fluorine-containing gas is in a range of 480 sccm-520 sccm. Merely by way of example, the gas flow rate of carbon tetrafluoride is 480 sccm, 490 sccm, 495 sccm, 500 sccm, 506 sccm, 513 sccm, 518 sccm, and 520 sccm. Further preferably, the gas flow rate of carbon tetrafluoride is 500 sccm. Correspondingly, the gas flow rate of trifluoromethane contained in the first fluorine-containing gas is 100 sccm.

In some embodiments, the first auxiliary gas comprises oxygen. In the first etching gas, the gas flow ratio of trifluoromethane to oxygen is 10:(19-21). The gas flow ratio may be a boundary value in 10:(19-21) or any integer or decimal value in the range. Further preferably, in the first etching gas, the gas flow ratio of trifluoromethane to oxygen is 10:20.

Continuing to take the four etching gases C₄F₈, CHF₃, CF₄ and O₂ in the aforementioned original process for etching as an example, the gas flow rates of CHF₃ and O₂ in the corresponding etching stages are 50 sccm and 50 sccm, respectively, and the gas flow rate ratio of CHF₃ to O₂ is 1:1. The gas flow ratio of trifluoromethane to oxygen in this embodiment is 10:(19-21). By comparison, it can be seen that this embodiment increases the gas flow rate of oxygen in the first etching gas. In this way, by increasing the flow rate of oxygen in the first etching gas, the new carbon-containing polymer generated by introducing too much carbon tetrafluoride can be solved, and the polymer defect problem in the etching process can be fundamentally reduced.

In some embodiments, the gas flow rate of the first auxiliary gas is in a range of 190 sccm-210 sccm. Merely by way of example, the gas flow rate of the first auxiliary gas is 190 sccm, 192 sccm, 195 sccm, 200 sccm, 204 sccm, 208 sccm, 210 sccm, etc. Further preferably, the gas flow rate of the first auxiliary gas is 200 sccm.

In some embodiments, a photoresist layer is formed on the passivation layer, and the first etching gas further comprises a second auxiliary gas for hardening the photoresist layer; and etching the passivation layer using a plurality sets of etching gases corresponding to the multi-layer structure comprises:

Etching corresponding layer structures in the passivation layer in stages using the photoresist layer as a mask and the plurality sets of etching gases; after etching the passivation layer, a remaining thickness of the photoresist layer is greater than a preset thickness value.

In an embodiment, as shown in FIG. 3, a photoresist layer 301 covers the passivation layer. Before etching the passivation layer, the photoresist layer may be etched to form an etching pattern, and then the etched photoresist layer is used as a mask, and the corresponding layer structures in the passivation layer are etched in stages using the plurality sets of etching gases, and a set of etching gases are used to etch the corresponding layer structures in the passivation layer in different stages. In the process of etching the passivation layer, each set of etching gases also etch a remaining non-opening region of the photoresist layer, resulting in a missing thickness of the photoresist layer. The second auxiliary gas for hardening the photoresist layer is added to the first etching gas. In the process of etching the passivation layer, the second auxiliary gas can harden the photoresist layer to reduce the etching amount of the first etching gas on the photoresist layer, so that the remaining thickness of a photoresist layer 301′ after etching is greater than the preset thickness value. In this way, by adding the second auxiliary gas to the first etching gas, the photoresist layer is hardened in advance, the remaining thickness of the photoresist layer is ensured, and the passivation layer in the non-opening region can be better protected.

In the case where the photoresist layer is formed on the passivation layer, after etching the passivation layer, photoresist removal can be first performed using, for example, an oxygen-containing plasma to remove the remaining photoresist layer on the unetched passivation layer, and then the above cleaning process is performed to clean the by-products on the wafer and the opening region.

In some embodiments, the second auxiliary gas comprises hydrogen, and a gas flow ratio of the second auxiliary gas to the first auxiliary gas is (1-2):(19-21). Taking the first auxiliary gas as oxygen and the second auxiliary gas as hydrogen as an example, the gas flow ratio of hydrogen to oxygen in the first etching gas is a boundary value of (1-2):(19-21) or any integer or decimal value in a ratio range. Taking the gas flow range of the first auxiliary gas as 190 sccm-210 sccm as an example, based on this ratio range, it can be determined that the gas flow rate of the second auxiliary gas is in a range of 10 sccm-20 sccm. Exemplarily, the gas flow rate of the second auxiliary gas is 10 sccm, 12 sccm, 14 sccm, 15 sccm, 18 sccm, 20 sccm, etc. Further preferably, the gas flow rate of the second auxiliary gas is 18 sccm. In this way, by setting the second auxiliary gas to comprise hydrogen, it is possible to ensure that the photoresist layer is hardened while ensuring that the adjusted gas composition meets the performance requirements for the opening morphology after etching.

In some embodiments, the preset thickness value is greater than or equal to 1000 angstroms. In this embodiment, the preset thickness value is 1000 angstroms. That is, after etching the passivation layer, the remaining thickness of the photoresist layer is greater than 1000 angstroms.

In practical applications, taking the first fluorine-containing gas as trifluoromethane and carbon tetrafluoride, the first auxiliary gas as oxygen, and the second auxiliary gas as hydrogen as an example, under the condition that the gas flow rate of trifluoromethane remains unchanged, within the above corresponding gas flow range, if the gas flow rate of carbon tetrafluoride is increased, the flow rate of oxygen is reduced, and the flow rate of hydrogen is increased. For example, if the gas flow rate of carbon tetrafluoride is 480 sccm, the gas flow rate of oxygen is 210 sccm, and the gas flow rate of hydrogen is 10 sccm. On the contrary, if the gas flow rate of carbon tetrafluoride is 480 sccm, the gas flow rate of oxygen is 190 sccm, and the gas flow rate of hydrogen is 20 sccm.

In some embodiments, the passivation layer further comprises an etching stop layer, and the etching stop layer is located between the metal layer and the oxide dielectric layer; the method further comprises:

After etching the passivation layer to the etching stop layer, etching the opening region using a second etching gas to remove the by-products generated during the etching process.

In some embodiments, as shown in FIG. 3, the passivation layer further comprises the oxynitride dielectric layer 305 and an etching stop layer 306. The oxide dielectric layer 304 wraps around surfaces of the oxynitride dielectric layer 305, the etching stop layer 306 and the metal layer 307, the etching stop layer 306 is located between the oxynitride dielectric layer 305 and the metal layer 307, the etching stop layer 306 covers the metal layer 307 to cover and protect the metal layer during the etching of the passivation layer. Exemplarily, a material of the etching stop layer may comprise but is not limited to TiN (titanium nitride). After etching the passivation layer to the etching stop layer, the second etching gas is used to etch the opening region, and plasma post etch treatment (PET) is performed. Since the by-products are formed in the process of etching to form the opening region, some by-products adhere to the opening region under the action of gravity. The by-products generated in the etching process are removed by performing plasma PET on the opening region.

In some embodiments, the second etching gas comprises a second fluorine-containing gas with a low carbon-fluorine ratio and a third auxiliary gas, and a ratio of the gas flow of the second fluorine-containing gas to the third auxiliary gas is 1:(18-20). The low carbon-fluorine ratio refers to a low content of carbon and fluorine. Specifically, the fluorine-containing etching gas generally comprises gases with low carbon-fluorine ratios such as CF₄, CHF₃, CH₂F₂, CH₃F, and gases with high carbon-fluorine ratios such as C₄F₈, C₄F₆, C₅F₈. Optionally, the second fluorine-containing gas in the second etching gas is selected from at least one gas with a low carbon-fluorine ratio such as CF₄, CHF₃, CH₂F₂, etc., instead of selecting a gas with a high carbon-fluorine ratio such as C₄F₈.

Exemplarily, the gas flow ratio of the second fluorine-containing gas to the third auxiliary gas is a boundary value of 1:(18-20) or any integer or decimal value in the range. Further preferably, in the first etching gas, the gas flow ratio of trifluoromethane to carbon tetrafluoride is 1:19.

In some embodiments, the second fluorine-containing gas comprises carbon tetrafluoride.

In some embodiments, the third auxiliary gas comprises oxygen.

In some embodiments, the gas flow rate of the third auxiliary gas is in a range of 1800 sccm-2000 sccm. The gas flow rate of the third auxiliary gas is 1800 sccm, 1800 sccm, 1800 sccm, 1800 sccm, 1800 sccm, 1800 sccm, 1800 sccm, etc. Further preferably, the gas flow rate of the first auxiliary gas is 1900 sccm. Accordingly, the gas flow rate of carbon tetrafluoride contained in the second fluorine-containing gas is in a range of 100 sccm.

It should be noted that, during the dry etching process, the etching gas in some etching stages may also comprise, but is not limited to, inert gases such as nitrogen and argon. In addition, compared to the original old process, the dry etching process in this embodiment can only adjust the gas composition and flow rates of the first etching gas and the second etching gas without adjusting other related etching process parameters in the old process. Merely by way of example, other related etching process parameters may also comprise: pressure of 50-400 mT, RF frequency of 200-1000 W, ESC temperature of 15-30° C., etc.

This embodiment reduces the active group CF2+ by removing the fluorine-containing gas with a high carbon-fluorine ratio and using the fluorine-containing gas with a low carbon-fluorine ratio. This is because under the same volume, temperature and pressure conditions, the molar number of the two gases is the same (the ideal gas state equation PV=nRT). The molecules of CF₄ and C₄F₈ contain 4 and 8 F atoms, respectively. Therefore, although their molar numbers are the same, the number of F atoms in C₄F₈ gas is twice that of CF₄ gas. The radio frequency electric field ionizes these molecules, and the degree of ionization depends on factors such as the structure of the molecules, the intensity of the electric field, and the temperature. However, since the number of F atoms in the C₄F₈ molecule is twice that of CF₄, if the degree of ionization of the two is the same, the number of F ions generated by C₄F₈ will be more than that of CF₄.

The test results show that as the active groups CF2+ decrease during the etching process, CF₄ can inhibit the formation of aluminum fluoride polymers. In addition, by increasing the proportion of the first auxiliary gas and the proportion of the third auxiliary gas during the etching process, the newly generated carbon-containing polymers can be removed, solving the problem of polymer defects in the etching process from the source. In this way, by improving the composition and ratio of the etching gases, the problem of polymer defects can be directly solved in one step, and the technical solution has good stability.

In order to demonstrate the technical effect of the technical solution of the present disclosure, comparative illustration is provided below in conjunction with Comparative Examples.

### Comparative Example 1

In this Comparative Example 1, the etching gas of the original old process is used to dry-etch the passivation layer on the wafer. Specifically, the etching gas in a Stage a comprises C₄F₈, CHF₃, CF₄ and O₂, and does not comprise H₂; the etching gas in a Stage c comprises C₄F₈ and O₂. Some etching process parameters for dry etching in a comparative document 1 are shown in Table 1 below:

TABLE 1

| | | | Gas flow rate/sccm | | | | |
|---|---|---|---|---|---|---|---|
| Stage | Pressure/mT | RF power/W | C₄F₈ | CHF₃ | CF₄ | O₂ | H₂ |
| a | 50 | 500 | 28 | 100 | 420 | 120 | 0 |
| b | 180 | 600 | 0 | 50 | 500 | 0 | 0 |
| c | 400 | 1000 | 0 | 100 | 1500 | 0 | 0 |

The Stage a refers to an etching stage of the oxide dielectric layer in the passivation layer, the Stage b refers to an etching stage of the oxynitride dielectric layer in the passivation layer, and the Stage c refers to the plasma etching post-processing PET stage.

### Example 1

In Example 1, for the first etching gas used to etch the oxide dielectric layer, the first fluorine-containing gas with a low carbon-fluorine ratio is CHF₃ and CF₄, the first auxiliary gas is O₂, and the second auxiliary gas is H₂, which does not contain C₄F₈. For the second etching gas, the second fluorine-containing gas with a low carbon-fluorine ratio is CF₄, and the third auxiliary gas is O₂. Some etching process parameters for dry etching in this embodiment are shown in Table 2 below:

TABLE 2

| | | | Gas flow rate/sccm | | | | |
|---|---|---|---|---|---|---|---|
| Stage | Pressure/mT | RF power/W | C₄F₈ | CHF₃ | CF₄ | O₂ | H₂ |
| a | 50 | 500 | 0 | 100 | 480 | 210 | 10 |
| b | 180 | 600 | 0 | 50 | 500 | 0 | 0 |
| c | 400 | 1000 | 0 | 100 | 1800 | 0 | 0 |

The Stage a refers to an etching stage of the oxide dielectric layer in the passivation layer, the Stage b refers to an etching stage of the oxynitride dielectric layer in the passivation layer, and the Stage c refers to the plasma PET stage.

### Example 2

The difference from Example 1 is that the gas flow rates of the first etching gas and the second etching gas are different. Some etching process parameters for dry etching in Example 2 are shown in Table 3 below:

TABLE 3

| | | | Gas flow rate/sccm | | | | |
|---|---|---|---|---|---|---|---|
| Stage | Pressure/mT | RF power/W | C₄F₈ | CHF₃ | CF₄ | O₂ | H₂ |
| a | 50 | 500 | 0 | 100 | 500 | 200 | 18 |
| b | 180 | 600 | 0 | 50 | 500 | 0 | 0 |
| c | 400 | 1000 | 0 | 100 | 1900 | 0 | 0 |

### Example 3

The difference from Example 1 is that the gas flow rates of the first etching gas and the second etching gas are different. Some etching process parameters for dry etching in Example 3 are shown in Table 4 below:

TABLE 4

| | | | Gas flow rate/sccm | | | | |
|---|---|---|---|---|---|---|---|
| Stage | Pressure/mT | RF power/W | C₄F₈ | CHF₃ | CF₄ | O₂ | H₂ |
| a | 50 | 500 | 0 | 100 | 520 | 190 | 20 |
| b | 180 | 600 | 0 | 50 | 500 | 0 | 0 |
| c | 400 | 1000 | 0 | 100 | 2000 | 0 | 0 |

Combining Tables 1-4 and FIG. 4, it can be seen that compared with the original old process of Comparative Example 1, the new process in Examples 1-3 removes the fluorine-containing gas C₄F₈ with a high carbon-fluorine ratio in the first etching gas in the Stage a, increases the proportion of CF₄ and O₂, and additionally adds H₂ to the first etching gas. In addition, in the Stage b, Examples 1-3 also increase the proportion of O₂ in the second etching gas.

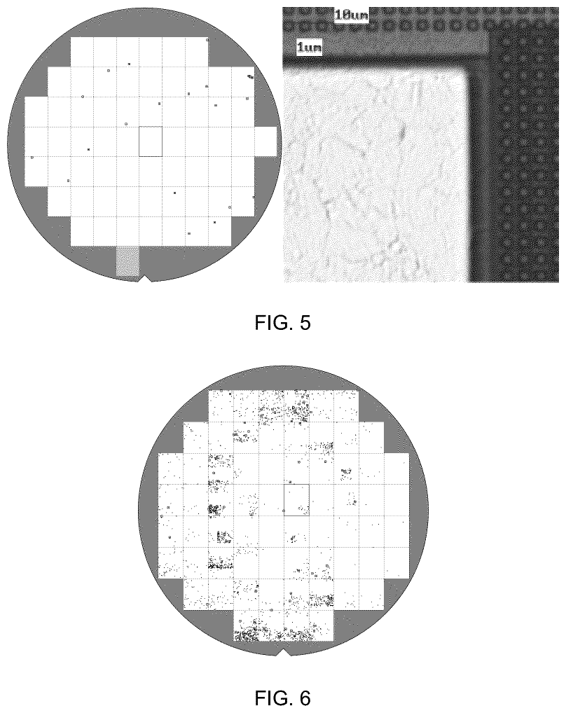

After the dry etching and the cleaning process, defect detection is performed on Comparative Example 1 and each embodiment. FIG. 1 is the defect detection result of the wafer formed by Comparative Example 1. It can be concluded from the schematic diagram of electron scanning on the left side of FIG. 1 and the optical micrograph of the chip unit on the right side that the wafer prepared by Comparative Example 1 contains a large number of polymer defects. FIG. 5 is a defect detection result of a wafer formed by Example 1. It can be concluded from the schematic diagram of electron scanning on the left side of FIG. 5 and the optical micrograph of the chip unit on the right side that the wafer prepared by Example 1 does not contain polymer defects. In addition, the wafer defect detection results of Example 2 and Example 3 also show that the wafer does not contain polymer defects.

In addition, in order to reflect the technical effect of the flow ranges of the plurality sets of etching gases used in the embodiments of the present disclosure, the following is an explanation in combination with Comparative Example 1 and Comparative Example 2.

The difference between the Comparative Example 1 and the Examples 1-3 is that: in the Stage a, the etching gas flow rate of CF₄ is less than 480 sccm-520 sccm, the etching gas flow rate of O₂ is less than 190 sccm-210 sccm, and the etching gas flow rate of H₂ is less than 10 sccm-20 sccm; in the Stage c, the etching gas flow rate of O₂ is less than 1800 sccm-2000 sccm. FIG. 6 is a schematic diagram of a defect detection result of a wafer prepared in the Comparative Example 1. It can be seen from the figure that when the etching gas flow rate range is lowered, some polymer defects still remain on the prepared wafer.

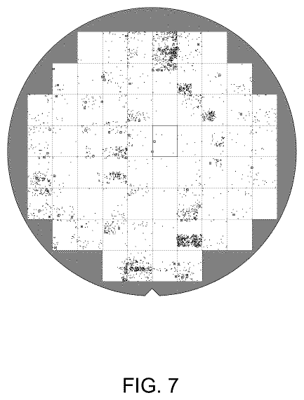

The difference between Comparative Example 2 and Examples 1-3 is that: in the Stage a, the etching gas flow rate of CF₄ is higher than the range of 480 sccm-520 sccm, the etching gas flow rate of O₂ is higher than the range of 190 sccm-210 sccm, and the etching gas flow rate of H₂ is higher than the range of 10 sccm-20 sccm; in the Stage c, the etching gas flow rate of O₂ is greater than the range of 1800 sccm-2000 sccm. FIG. 7 is a schematic diagram of a defect detection result of a wafer prepared in the Comparative Example 2. It can be seen from the figure that when the etching gas flow rate range is increased, some polymer defects still remain on the prepared wafer.

The test results show that in the Stage a, if the flow rate of the first auxiliary gas O₂ is less than 190 sccm, new polymer defects may remain; if the flow rate of the first auxiliary gas O₂ is greater than 210 sccm, the etching rate of the photoresist layer increases, resulting in insufficient protection of the remaining thickness of the photoresist layer. If the flow rate of the second auxiliary gas H₂ is less than 10 sccm, the remaining thickness of the photoresist layer is insufficient for protection; if the flow rate of the second auxiliary gas H₂ is greater than 20 sccm, the hardened layer of the photoresist layer is too much, which is not conducive to the removal of carbon-containing polymers.

Some embodiments of the present disclosure further provide a semiconductor device, which is prepared using any of the method for manufacturing the semiconductor device.

Some embodiments of the present disclosure further provide a chip, which comprises the semiconductor device described in any of the above embodiments.

Some embodiments of the present disclosure further provide an electronic apparatus, which comprises the semiconductor device and a printed circuit board (PCB) described in any of the above embodiments. The semiconductor device and the printed circuit board are electrically connected to achieve signal communication.

In some embodiments, the electronic apparatus is, for example, a consumer electronic product, a home electronic product, a vehicle-mounted electronic product, etc. The consumer electronic product may comprise a mobile phone, a tablet computer (pad), a laptop, an e-reader, a personal computer (PC), a personal digital assistant (PDA), a desktop display, a smart wearable product (e.g., a smart watch, and a smart bracelet), a virtual reality (VR) terminal device, an augmented reality (AR) terminal device, a drone, etc. The home electronic product may comprise a smart door lock, a TV, a remote control, a refrigerator, a rechargeable small household appliance (e.g., a soybean milk machine and a sweeping robot), etc. The vehicle-mounted electronic product may comprise a vehicle navigator, a vehicle DVD, etc. The electronic apparatus may also be any intermediate product comprising the semiconductor device. The embodiments of the present disclosure do not impose any special limitations on the specific form of the above electronic apparatus.

After the semiconductor device is packaged, it can be used in the electronic apparatus in the form of a chip. Of course, it can also be used directly in the electronic apparatus without packaging.

The technical effects that can be achieved by the electronic apparatus provided in the embodiments of the present disclosure are the same as the technical effects that can be achieved by the semiconductor device described in any of the above embodiments, which are not repeated here.

It should be noted that the above sequence of the embodiments of the present disclosure is for description only and does not represent the advantages and disadvantages of the embodiments. The above specific embodiments of this specification are described. Other embodiments are within the scope of the attached claims. In some cases, the actions or steps recorded in the claims can be performed in an order different from that in the embodiments and still achieve the desired results. In addition, the processes depicted in the drawings do not necessarily require the specific order or continuous order shown to achieve the desired results. In some embodiments, multitasking and parallel processing are also possible or may be advantageous.

Each embodiment in the present disclosure is described in a progressive manner, and the same or similar parts between the embodiments can be referred to each other, and each embodiment focuses on the differences from other embodiments. In particular, for the device, apparatus or equipment embodiment, since it is basically similar to the method embodiment, the description is relatively simple, and the relevant parts can be referred to the partial description of the method embodiment.

The above description is only a preferred embodiment of the present disclosure and is not intended to limit the present disclosure. Any modifications, equivalent substitutions, improvements, etc. made within the spirit and principles of the present disclosure should be included in the protection scope of the present disclosure.

What is claimed is:

1. A method for manufacturing a semiconductor device, comprising:
providing a wafer, wherein a metal layer containing aluminum and a passivation layer are formed on the wafer, the passivation layer is a multi-layer structure sequentially stacked on the metal layer, and the passivation layer comprises an oxide dielectric layer;
etching the passivation layer using a plurality sets of etching gases corresponding to the multi-layer structure to form an opening region exposing a portion of the metal layer;
performing a cleaning process to at least clean byproducts in the opening region;
wherein the plurality sets of etching gases comprise a first etching gas for etching the oxide dielectric layer, the first etching gas comprises a first fluorine-containing gas with a low carbon-fluorine ratio and a first auxiliary gas, and the first auxiliary gas is configured to remove a carbon-containing polymer generated during an etching process.

2. The method according to claim 1, wherein the first fluorine-containing gas comprises trifluoromethane and carbon tetrafluoride; in the first etching gas, a gas flow ratio of the trifluoromethane to the carbon tetrafluoride is 5:(24-26); and/or
a gas flow ratio of the first fluorine-containing gas to the first auxiliary gas is less than 4.

3. The method according to claim 2, wherein the first auxiliary gas comprises oxygen;
in the first etching gas, a gas flow ratio of the trifluoromethane to the oxygen is 10:(19-21).

4. The method according to claim 3, wherein a gas flow range of carbon tetrafluoride contained in the first fluorine-containing gas is in a range of 480 sccm-520 sccm, and a gas flow range of the first auxiliary gas is in a range of 190 sccm-210 sccm.

5. The method according to claim 1, wherein a photoresist layer is formed on the passivation layer, and the first etching gas further comprises a second auxiliary gas for hardening the photoresist layer; and etching the passivation layer using a plurality sets of etching gases corresponding to the multi-layer structure comprises:
etching corresponding layer structures in the passivation layer in stages using the photoresist layer as a mask and the plurality sets of etching gases; after etching the passivation layer, a remaining thickness of the photoresist layer is greater than a preset thickness value.

6. The method according to claim 5, wherein the second auxiliary gas comprises hydrogen, and a gas flow ratio of the second auxiliary gas to the first auxiliary gas is (1-2):(19-21).

7. The method according to claim 5, wherein the preset thickness value is greater than or equal to 1000 angstroms.

8. The method according to claim 1, wherein the passivation layer further comprises an etching stop layer, and the etching stop layer is located between the metal layer and the oxide dielectric layer; the method further comprises:
after etching the passivation layer to the etching stop layer, etching the opening region using a second etching gas to remove the by-products generated during the etching process.

9. The method according to claim 8, wherein the second etching gas comprises a second fluorine-containing gas with a low carbon-fluorine ratio and a third auxiliary gas, and a gas flow ratio of the second fluorine-containing gas to the third auxiliary gas is 1:(18-20).

10. The method according to claim 9, wherein the second etching gas satisfies at least one of:
the second fluorine-containing gas comprising the carbon tetrafluoride;
the third auxiliary gas comprising the oxygen;
a gas flow range of the third auxiliary gas is in a range of 1800 sccm-2000 sccm.

11. A semiconductor device, wherein the semiconductor device is manufactured by the method according to claim 1.
